(19) United States
(12) Patent Application Publication
(10) Pub. No.: US 2011/0169484 A1
(43) Pub. Date: Jul. 14, 2011

(54) MAGNETIC-LABEL SENSOR AND CARTRIDGE

(75) Inventors: Hans Van Zon, Waalre (NL); Mikhail Ovsyanko, Eindhoven (NL); Jeroen Hans Nieuwenhuis, Waalre (NL)

(73) Assignee: KONINKLIJKE PHILIPS ELECTRONICS N.V., EINDHOVEN (NL)

(21) Appl. No.: 13/119,974

(22) PCT Filed: Sep. 16, 2009
(86) PCT No.: PCT/IB2009/054046

§ 371 Date: Mar. 21, 2011

(30) Foreign Application Priority Data
Sep. 26, 2008 (EP) 08165246.3

(51) Int. Cl. G01R 33/00

(52) U.S. Cl. 324/214

(57) ABSTRACT

A cartridge (1,3) for a magnetic-label sensor, in particular for a magnetic-label biosensor, comprises a sensor area (4) a fluid channel (2) in contact with said sensor area and first (A) and second (B1, B2) reservoirs in fluid communication with said fluid channel. The first reservoir comprises a first type of magnetic particles (8) and the second reservoir comprises a second type of magnetic particles (8a). The first type of magnetic particles are functionalized for binding with said sensor area, whereas the second type of magnetic particles are non-functionalized for binding with said sensor area. The magnetic particles (8, 8a) are manipulated using magnet (13). Detection is based on frustrated total internal reflection (FTIR) is hereby light from laser/LED (II) is reflected at sensor area (4) and detected by photodetector/CCD(12).

### FIELD OF THE INVENTION

The present invention relates to a magnetic-label sensor, in particular to a magnetic-label biosensor, and a cartridge for such a sensor.

### BACKGROUND OF THE INVENTION

The demand for biosensors is increasingly growing these days. Usually, biosensors allow for the detection of a given specific molecule within an analyte, wherein the amount of said molecule is typically small. For example, one may measure the amount of drugs or cardiac markers within saliva or blood. Therefore, target particles, for example super-paramagnetic label beads, are used which bind to a specific binding site or spot only, if the molecule to be detected is present within the analyte. One known technique to detect these label particles bound to the binding spot is frustrated total internal reflection (FTIR). Therein, light is coupled into the sample at an angle of total internal reflection. If no particles are present close to the sample surface, the light is completely reflected. If, however, label particles are bound to said surface, the condition of total internal reflection is violated, a portion of the light is scattered into the sample and thus the amount of light reflected by the surface is decreased. By measuring the intensity of the reflected light with an optical detector, it is possible to estimate the amount of particles bound to the surface. This allows for an estimate of the amount of the specific molecules of interest present within the analyte or sample.

This technique as well as other magnetic-label sensors, in particular biosensors, critically depends on the magnetic attraction of the beads or magnetic labels, also referred to as actuation. Magnetic actuation is in particular essential in order to increase the performance (speed) of the biosensor for point-of-care applications. The direction of the magnetic actuation can be either towards the surface or sensor area where the actual measurement is carried out or away from this sensor surface. In the first case, magnetic actuation allows for the enhancement of concentration of magnetic particles near the sensor surface, thus speeding up the binding process of the magnetic particles to the sensor area. In the second case, particles are removed from the sensor surface which is called magnetic washing. Magnetic washing can replace the traditional wet washing step, where fluids are used to remove excessive particles. Magnetic washing is more accurate and reduces the number of operating steps.

Due to the magnetic attraction, the number of particles or labels near the sensor area increases and the sensor signal increases accordingly. However, once a certain particle density at the sensor surface is approached, it is not possible to increase the sensor signal any further. At this point, the maximum capacity of the surface has been reached. This maximum capacity is caused by magnetic repulsion between particles and/or chains of particles at the sensor surface. This effect limits the amount of particles which can be accumulated on the surface and thus limits the signal obtained from the (bio-)sensor. This disadvantageously reduces the signal-to-noise ratio of the sensor and thus the detection limit (expressed as the minimum concentration of, e.g., cardiac markers which can still be detected in, e.g., blood). Especially for cardiac marker applications where concentrations in the order of 100 fM have to be measured, it is essential to achieve a low detection limit.

### SUMMARY OF THE INVENTION

It is therefore an object of the present invention to provide an improved magnetic-label sensor, in particular a magnetic-label biosensor, as well as a cartridge therefor. It is in particular an object of the present invention to provide a magnetic-label sensor and a cartridge which allow for a reduction of the detection limit and/or an increase in the signal-to-noise ratio.

These objects are achieved by the features of the claims.

As outlined above, the detection limit as well as the signal to noise ratio is correlated with the maximum capacity of the sensor surface. The present invention is therefore based on the idea to increase the maximum capacity of the sensor surface. According to the present invention, this increase of the maximum capacity of the sensor surface is achieved by adding additional particles to the cartridge which may be used to force the magnetic labels towards the sensor surface. The term capacity defines the amount of label particles at the sensor surface and as the label particles are detected and lead to the signal, the amount of label particles determine the signal. Consequently the signal amplitude to be achieved with a certain sensor surface is related to the amount of label particles that can be detected, as described.

The present invention provides a cartridge for a magnetic-label sensor, in particular for a magnetic-label biosensor, comprising a sensor area, a fluid channel in contact with said sensor area and first and second reservoirs in fluid communication with said fluid channel. The term magnetic-label sensor defines a sensor in which magnetic labels are applied to be attached to further particles, for instance an analyte, as known in the art. The first reservoir comprises a first type of magnetic particles and the second reservoir comprises a second type of magnetic particles. The first type of magnetic particles are functionalized for binding with said sensor area, whereas the second type of magnetic particles are non-functionalized for binding with said sensor area. Accordingly, the first type of magnetic particles may be used as in a common biosensor. The first type of magnetic particles are preferably super-paramagnetic label beads which bind to a specific binding site or sensor area only, if the molecule to be detected is present within the analyte. The second type of magnetic particles is preferably also super-paramagnetic, yet these particles are not functionalized for binding with said sensor area. The second type of magnetic particles are merely used to generate a force onto the first type of magnetic particles in order to press or force them towards the sensor area. The second type of magnetic particles also reduces the diffusion of the first type of particles when the magnetic field is switched off, thereby increasing the time that the first type of particles are near the binding surface and therefore increasing the binding probability. In the context of the present application the term “non-functionalized” can also imply that the second type of magnetic particles are substantially less functionalized than the first type of magnetic particles. In any case, the second type of particles need not be as much functionalized as the first type of particles.

The term “reservoir” is to be understood broadly in the present application. The first and second reservoirs may be recesses, cavities or the like which are adapted to accommodate the first and second types of particles. However, the first and second types of magnetic particles can also be directly deposited onto the surface of the cartridge without any recess or the like being necessary. In this case the term “reservoir” is to be understood as the region or area where the particles are deposited.

For this purpose, it is preferable that under magnetic actuation the first type of magnetic particles reach the sensor area substantially before the second type of magnetic particles. According to a particularly preferred embodiment of the present invention the distance between the first reservoir and the sensor area is smaller than the distance between the second reservoir and the sensor area. Thus, if the magnetic actuation is switched on the first type of magnetic particles will due to the shorter distance reach the sensor area faster than the second type of magnetic particles. Consequently, the first type of magnetic particles may bind to the sensor area, whereas the second type of magnetic particles may pile up on the first type of magnetic particles to generate a force.

According to another preferred embodiment of the present invention the magnetic susceptibility of the first type of magnetic particles is larger than the magnetic susceptibility of the second type of magnetic particles. Additionally or alternatively, the volume of the first type of magnetic particles may be larger than the volume of the second type of magnetic particles. Accordingly, the magnetic moment induced in the first type of magnetic particles by an external magnetic field will be larger than the magnetic moment induced in the second type of magnetic particles. The force onto the first type of magnetic particles and consequently the velocity of the first type of magnetic particles will be larger than that onto/of the second type of magnetic particles. In this case, the distance between the first reservoir and the sensor area and the distance between the second reservoir and the sensor area may be equal. However, it is also possible to combine those effects.

Of course, other effects may be used as well to achieve the separation of first and second types of magnetic particles at the sensor surface. For example, the first type of magnetic particles and the second type of magnetic particles may have a different size, e.g. diameter. Alternatively, it is also possible that the first type of magnetic particles and the second type of magnetic particles are provided within the same reservoir, the first type of magnetic particles being placed on top of the second type of magnetic particles. Accordingly, the present invention provides a cartridge for a magnetic-label sensor comprising a sensor area, a fluid channel in contact with said sensor area and a reservoir comprising a first type of magnetic particles and a second type of magnetic particles. The reservoir is in fluid communication with said fluid channel, wherein the first type of magnetic particles are functionalized and the second type of magnetic particles are non-functionalized for binding with said sensor area. The distance between said first type of particles and the sensor area is smaller than the distance between said second type of particles and the sensor area. According to a further preferred embodiment of the present invention a portion of the fluid channel between the second reservoir and the sensor area comprises means for delaying the movement of particles from the second reservoir towards the sensor area. The delay means may, e.g., comprise steps in the wall of said fluid channel. Thus, the second type of magnetic particles which are actuated from the second reservoir towards the sensor area will be slowed down or delayed by said steps.

According to another aspect of the present invention a magnetic-label sensor, in particular a magnetic-label biosensor, is provided. The sensor comprises means for magnetic actuation and a cartridge. The cartridge comprises a sensor area, a fluid channel in contact with said sensor area and first and second types of magnetic particles, wherein the first type of magnetic particles are functionalized and the second type of magnetic particles are non-functionalized for binding with said sensor area. The sensor further comprises means for detecting particles present at the sensor area of said cartridge and means for actuating said first and second types of magnetic particles towards the sensor area. Therein, the first type of magnetic particles reaches the sensor area substantially before the second type of magnetic particles.

The cartridge of said magnetic-label sensor may, in particular, be the cartridge described above. For example, said first and second types of magnetic particles may be located in first and second reservoirs, wherein the distance between the first reservoir and the sensor area is smaller than the distance between the second reservoir and the sensor area. Alternatively or additionally the magnetic susceptibility of the first type of magnetic particles may be larger than the magnetic susceptibility of the second type of magnetic particles.

According to a particular embodiment of the present invention, the means for magnetic actuation of the magnetic-label sensor is adapted for generating a magnetic flux such that a force onto the first type of magnetic particles is generated which is larger than a force acting on the second type of magnetic particles. Accordingly, the first type of magnetic particles will reach the sensor area substantially before the second type of magnetic particles, even though their magnetic susceptibility is equal and they are provided at the same distance from the sensor area.

The cartridge and the sensor according to the present invention are advantageous over the prior art, since they allow for an increased surface density of the first type of magnetic particles. Thus, the maximum capacity of the sensor surface can be increased which leads to a lower detection limit and accordingly to a better signal-to-noise ratio.

These and other aspects of the invention will be apparent from and elucidated with reference to the embodiment(s) described hereinafter.

### BRIEF DESCRIPTION OF THE DRAWINGS

FIG. 1 schematically shows the functional principle of FTIR.

FIG. 2 shows a graph of the biosensor signal S(t) versus time during continuous magnetic attraction.

FIG. 3a shows a preferred embodiment of a cartridge according to the present invention.

FIG. 3b shows another preferred embodiment of a cartridge according to the present invention.

FIG. 4a shows the process of actuation according to the prior art.

FIG. 4b schematically shows the process of actuation according to the present invention.

### DETAILED DESCRIPTION OF EMBODIMENTS

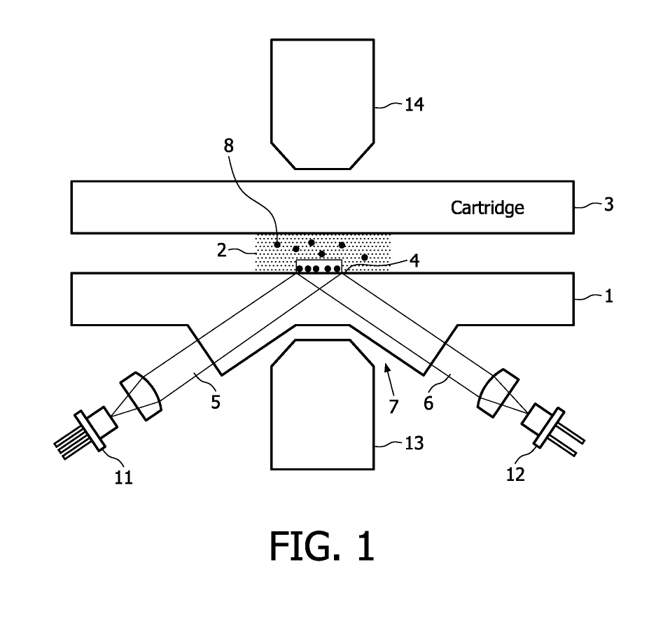

FIG. 1 schematically shows the functional principle of the optical detection method of Frustrated Total Internal Reflection (FTIR). The cartridge shown comprises a bottom portion 1 and a cover portion 3 with a fluid channel 2 therebetween. The fluid channel 2 is adapted to be filled with a sample and is closed or covered by the cover portion 3. At the bottom, the fluid channel 2 is confined by a sensor surface or sensor area 4, both terms are used in the following. Light from a laser or LED 11 enters the bottom portion 1 along a first optical path 5, is reflected at said sensor surface 4 and exits bottom portion 1 along a second optical path 6. The bottom portion 1 forms a recess 7, which is adapted to accommodate a means 13 for providing a magnetic field.

Once the fluid channel 2 is filled or supplied with a fluid sample, the super-paramagnetic label particles 8, which have been supplied in a dry form, disperse into solution with the fluid sample. The terms magnetic particles and magnetic label particles are used equivalent herin. Using magnet 13, the super-paramagnetic label particles 8 may be accelerated towards the sensor surface 4, where they may bind to the sensor surface 4 if the specific molecule to be detected is present in the fluid sample. A variety of different binding methods for binding the label particles 8 directly or indirectly to the sensor surface 4 is known in the art. The sensor surface 4 may comprise to this end an assay for the binding of the label particles 8 at it. After some time sufficient for binding, the magnet 13 may be used in order to remove the label particles 8, which are not bound to the sensor surface 4, from said sensor surface 4. To this end the power of the magnetic field generated by the magnet 13 is adjusted in a way not to break the bindings but essentially only remove label particles 8 not bound. After this so called “washing” step, the sensor surface 4 is illuminated with a laser or LED 11. The light of the laser or LED 11 is reflected at the sensor surface 4 and detected by a detector 12, which may be a photodiode or a CCD camera. Typically, the optical element or detector 12 is read out continuously during the assay and the progress of the binding process is monitored. For the sake of clarity the term assay is also used as a procedure where a property or concentration of an analyte in the fluid is measured. However, alternatively an image may be obtained at the detector 12 out of the received light before the assay without bound label particles 8 and one image after the assay with bound label particles 8 and the differences may then be compared. The optical path 5 of the incoming light is chosen such that the condition of total internal reflection is fulfilled. In that case, an evanescent optical field is generated, which typically penetrates only 50 to 100 nm, typically up to 70 nm into the fluid channel 2 for a specific wavelength of the lightsource, this is the laser or LED 11. Lightsources with other wavelengths will have different evanescent field lengths. Thus, only if label particles 8 are that close to the sensor surface 4, the evanescent field is disturbed leading to a decrease in the reflected intensity.

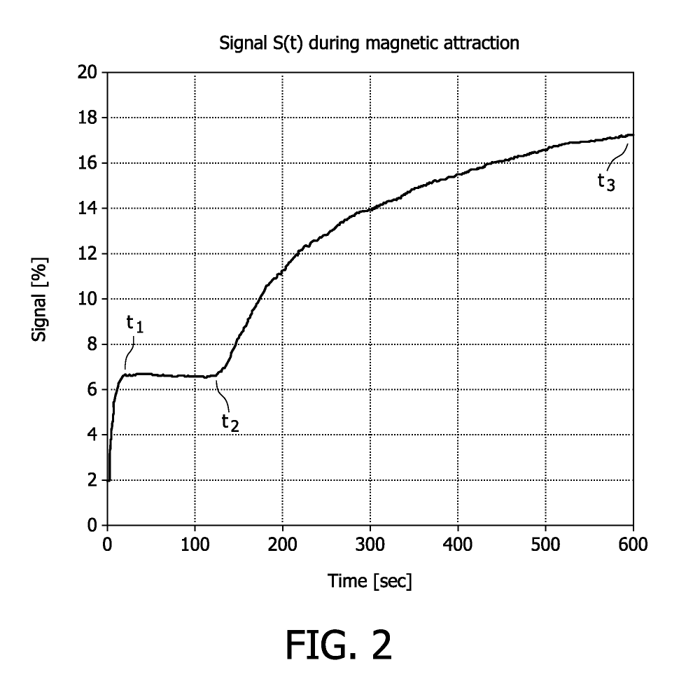

FIG. 2 shows a graph of a typical signal S(t) which is observed when label particles 8, also denominated as beads, with a certain concentration in the channel 2 are attracted towards the sensor surface 4 by means of a continuous magnetic field. X-axis designates time t and y-axis designates the signal strength in percentage of maximum. The signal S(t) is after a certain time nearly directly proportional to the density of beads on the sensor surface 4. A rise in the signal therefore means an increase of the number of beads on the sensor surface 4 in the region of the evanescent field. A constant signal means that no additional beads are entering the evanescent field region. During a first stage of the continuous magnetic attraction (0<t<t₁) magnetic label particles 8, i.e. beads or label beads, are transported in a mainly vertical direction towards the sensor area, the area at the sensor surface 4 at which the optical detection takes place. This is reflected by an increase of roughly 7% until t₁. The signal increases continuously in time because the magnetic label particles 8 can reach the region where they are optically detectable. After a certain time t₁ the signal stabilizes because the maximum density of label particles 8 on the sensor surface 4 has been reached. In other words, the density of label particles 8 within the detection zone (up to a height of roughly 70 nm) does not change anymore although it is still possible that label particles 8 are accumulating above said zone (i.e. at heights above roughly 70 nm).

The maximum capacity of the sensor surface 4 is a direct consequence of the presence of a magnetic field generated by the magnet 13. Under the influence of said magnetic field initially isolated, mobile label particles 8 cluster to larger chains of label particles 8, especially at the sensor surface 4. At some point, the chains of label particles 8 are becoming less mobile on the sensor surface 4 and it is not possible anymore to obtain the lowest energy state which would be the clustering of all chains into one very long chain of particles on the sensor surface 4. In this state the chains of magnetic label particles 8 repel each other. If other forces were absent the chains would readily redistribute over the sensor surface 4 to lower the total energy. However, due to further lateral forces within the plane of the sensor surface 4, which are also caused by the actuation magnet 13, the chains of magnetic label particles 8 are compressed and the distance between those chains is reduced. In this high-energy-state the system does not allow for any further label particles 8 to approach the sensor surface 4.

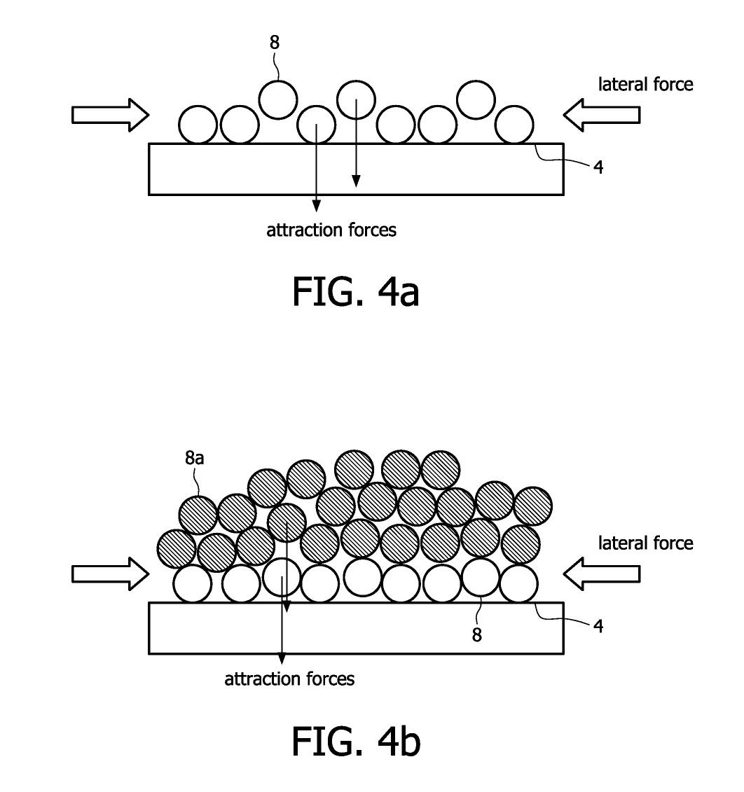

This situation is schematically sketched in FIG. 4a. The maximum density of magnetic label particles 8 at the sensor surface 4 is basically caused by an equilibrium of forces: the attraction forces onto the label particles 8 towards the sensor surface 4, the lateral forces onto the label particles 8 towards the center of the sensor surface 4 and the repulsive forces between the label particles 8 or between chains of label particles 8 (not indicated in FIG. 4a).

Interestingly, referring again to FIG. 2, it is observed that after a certain time t₂ the signal S(t) starts to increase again. This implies that magnetic label particles 8 are again entering the region at heights below about 70 nm, which is optically detectable. Apparently, the density of magnetic label particles 8 at the sensor surface 4 is increasing beyond the threshold discussed above. This can be explained by an increase of the force acting onto the magnetic label particles 8 towards the sensor surface 4, which is caused by beads further away from the sensor surface 4 being laterally attracted towards the sensor surface 4. If more and more label particles 8 pile up above the label particles 8 shown in FIG. 4a, those additional label particles 8 are also attracted by the magnetic field and thus generate an additional compression force onto the bottom layer of label particles 8. This is schematically shown in FIG. 4b, where additional particles 8a have been piled up on the bottom layer of particles 8, which are therefore compressed or forced towards the sensor surface 4. The balance of forces mentioned above has simply been shifted in favor of the attraction forces onto magnetic particles 8 towards the sensor surface 4. This is reflected by the signal increase beyond time t₂ shown in FIG. 2.

The present invention is based on the idea to make use of this effect in order to increase the maximum capacity of the sensor surface 4.

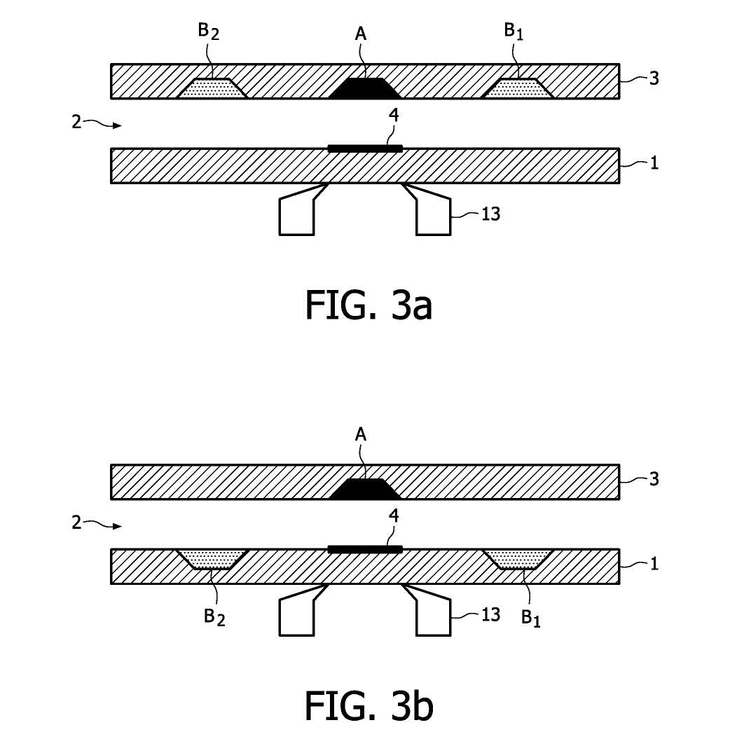

A simple sketch of a preferred embodiment of a cartridge according to the present invention is shown in FIG. 3a. The cartridge comprises a bottom portion 1 having a sensor area 4 and a cover portion 3. Means 13 for generating a magnetic field are also shown. Of course, the bottom portion 1 of the cartridge may also have the shape shown in FIG. 1 which is particularly preferred if the cartridge is used for FTIR. The cover portion 3 of the cartridge comprises a first reservoir A comprising a first type of magnetic label particles 8. Furthermore, two reservoirs B₁ and B₂ comprising a second type of magnetic label particles 8a are provided in the cover portion 3 of the cartridge. All three reservoirs are in fluid communication with a fluid channel 2 between the cover portion 3 and the bottom portion 1. In accordance with the present invention the first type of magnetic label particles 8 contained in the first reservoir A are functionalized for binding with the sensor surface 4 and the second type of magnetic label particles 8a contained in the two reservoirs B₁ and B₂ are non-functionalized for binding with said sensor area. By functionalization the first type of magnetic label particles 8 is designed to be attached to the sensor surface 4 by a variety of methods known in the art. The non-functionalized label particles 8a to the contrary donot possess any binding means to be attached to the sensor surface 4.

As will be apparent from the sketch shown in FIG. 3a, once a magnetic field for actuation is switched on, the magnetic label particles 8 contained in the reservoirs A, B₁ and B₂ will be attracted or actuated towards the sensor area 4. However, since the distance between the first reservoir A and the sensor area 4 is much smaller than the distance between either reservoir B₁ or reservoir B₂ and the sensor area 4, the first type of magnetic label particles 8 contained within reservoir A will reach the sensor area 4 before the second type of magnetic particles contained in reservoirs B₁ and B₂. Accordingly, one will achieve a situation as shown in FIG. 4b, wherein the light particles 8 below are of the first functionalized type and the dark particles 8a above are of the second non-functionalized type. Thus, the first type of magnetic label particles 8 may bind to the sensor surface 4, whereas the second type of magnetic label particles 8 are in this connection only used to increase the force onto the first type of magnetic label particles 8.

It will be apparent to the skilled person that the ideal situation sketched in FIG. 4b may not always be achieved in an actual experiment. It might rather happen that some of the non-functionalized particles 8a will also reach the sensor area 4, whereas some of the functionalized particles 8 will pile up in layers above the bottom layer near to the surface of the sensor area 4. In accordance with the functionality of the present invention the functionalized label particles 8 reach the sensor area 4 substantially before the non-functionalized label particles 8a, which means that a majority of the functionalized label particles 8 reach the sensor area 4 before the majority of the non-functionalized label particles 8a.

In addition to the difference in distance from the sensor surface 4, the first and second types of magnetic particles 8, 8a contained in reservoirs A and B₁/B₂ may also have different properties. For example the second type of magnetic label particles 8a may be larger or the magnetic susceptibility of the first type of magnetic label particles 8 may be higher than the magnetic susceptibility of the second type of magnetic label particles 8a. Additionally, the means 13 for generating a magnetic field may be designed in such a manner that the force onto the first type of magnetic label particles 8 generated by the magnetic flux is larger than the force onto the second type of magnetic label particles 8a.

FIG. 3b shows an alternative embodiment of a cartridge according to the present invention. In contrast to the embodiment shown in FIG. 3a, the reservoirs B₁ and B₂ are provided in the bottom portion 1 of the cartridge. In this embodiment, it may be particularly preferred to provide tiny steps in the bottom portion 1 or substrate between the reservoirs B₁ and B₂ and the sensor surface 4. Thus, the arrival of the second type of magnetic particles 8a contained in the reservoirs B₁ and B₂ is delayed compared to the arrival of the first type of magnetic particles 8 contained in the reservoir A when both are released by liquid sample at the same time. By this means the arrangement of label particles 8, 8a as shown in FIG. 4a is achieved with the first type of magnetic label particles 8 nearer to the sensor surface 4 than the second type of magnetic label particles 8a.

The skilled person will understand that the embodiments shown in FIGS. 3a and 3b are to be understood exemplary. For example, instead of providing two reservoirs B₁ and B₂ there may be provided only a single reservoir B₁ for the second type of magnetic label particles 8a or three, four or more reservoirs for the second type of magnetic label particles 8a. Furthermore, combinations of the embodiment shown in FIG. 3a with the embodiment shown in FIG. 3b are possible as well. Instead of providing the reservoirs in the bottom portion 1 or cover portion 3 of the cartridge some or all of the reservoirs may also be provided in sidewalls of the fluid channel 2. The shape of the cartridge may also be optimized for a certain detection technique such as FTIR (confer the shape shown in FIG. 1).

Although the present invention has been described with reference to FTIR, it should be apparent that the cartridge and/or the sensor according to the present invention may be used with any detection technique.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measured cannot be used to advantage. Any reference signs in the claims should not be construed as limiting the scope.

1. A cartridge for a magnetic-label sensor comprising a sensor area (4), a fluid channel (2) in contact with said sensor area (4), a first reservoir (A) comprising a first type of magnetic particles (8) and at least a second reservoir (B₁, B₂) comprising a second type of magnetic particles (8a), both reservoirs (A, B₁, B₂) being in fluid communication with said fluid channel (2), wherein the first type of magnetic particles (8) are functionalized and the second type of magnetic particles (8a) are non-functionalized for binding with said sensor area (4).

2. Cartridge according to claim 1, wherein the distance between the first reservoir (A) and the sensor area (4) is smaller than the distance between the second reservoir (B₁, B₂) and the sensor area (4).

3. Cartridge according to claim 1, wherein the magnetic susceptibility of the first type of magnetic particles (8) is larger than of the second type of magnetic particles (8a).

4. Cartridge according to claim 1, wherein the volume of the first type of magnetic particles (8) is larger than of the second type of magnetic particles (8a).

5. A cartridge for a magnetic-label sensor comprising a sensor area (4), a fluid channel (2) in contact with said sensor area (4) and a reservoir (A) comprising a first type of magnetic particles (8) and a second type of magnetic particles (8a), said reservoir (A) being in fluid communication with said fluid channel (2), wherein the first type of magnetic particles (8) are functionalized and the second type of magnetic particles (8a) are non-functionalized for binding with said sensor area (4) and wherein the distance between said first type of particles (8) and the sensor area (4) is smaller than the distance between said second type of particles (8a) and the sensor area (4).

6. Cartridge according to claim 1, wherein a portion of the fluid channel (2) between the second reservoir (B₁, B₂) and the sensor area (4) comprises means for delaying the movement of particles from the second reservoir towards the sensor area.

7. Cartridge according to claim 6, wherein said delay means comprises steps in the wall of said fluid channel.

8. A magnetic-label sensor comprising
a) means (13) for magnetic actuation,
b) a cartridge comprising a sensor area (4), a fluid channel (2) in contact with said sensor area (4) and first and second types of magnetic particles (8, 8a), wherein the first type of magnetic particles (8) are functionalized and the second type of magnetic particles (8a) are non-functionalized for binding with said sensor area (4),
c) means (12) for detecting particles present at the sensor area of said cartridge, and
d) means for actuating said first and second types of magnetic particles (8, 8a) towards the sensor area (4), wherein the first type of magnetic particles (8) reach the sensor area (4) substantially before the second type of magnetic particles (8a).

9. Sensor according to claim 8, said first and second types of magnetic particles (8, 8a) being located in first and second reservoirs (A, B₁, B₂), wherein the distance between the first reservoir (A) and the sensor area (4) is smaller than the distance between the second reservoir (B₁, B₂) and the sensor area (4).

10. Sensor according to claim 8, wherein the magnetic susceptibility of the first type of magnetic particles (8) is larger than of the second type of magnetic particles (8a).

11. Sensor according to claim 8, wherein the volume of the first type of magnetic particles (8) is larger than of the second type of magnetic particles (8a).

12. Sensor according to claim 10, wherein a portion of the fluid channel (2) between the second reservoir (B₁, B₂) and the sensor area (4) comprises means for delaying the movement of particles from the second reservoir towards the sensor area.

13. Sensor according to claim 9, wherein the means for magnetic actuation (12) is adapted for generating a magnetic flux such that a force onto the first type of particles (8) is generated which is larger than a force acting on the second type of particles (8a).
